(19) United States
(12) Patent Application Publication
(10) Pub. No.: US 2010/0279485 A1
(43) Pub. Date: Nov. 4, 2010

(54) METHOD OF MANUFACTURING SEMICONDUCTOR DEVICE

(75) Inventor: Shigeo ISHIKAWA, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory, Inc., Tokyo (JP)

(21) Appl. No.: 12/768,310

(22) Filed: Apr. 27, 2010

(30) Foreign Application Priority Data
Apr. 30, 2009 (JP) 2009-110882

(51) Int. Cl. H01L 21/02; H01L 21/283

(52) U.S. Cl. 438/396; 438/666; 257/E21.011; 257/E21.159

(57) ABSTRACT

A method of manufacturing a semiconductor device may include, but is not limited to the following processes. A first contact plug is formed in a first insulating film. A barrier film is formed on the first insulating film. A second insulating film is formed on the barrier film. A support film is formed on the second insulating film. A first electrode is formed so as to penetrate the support film and the second insulating film. The first electrode is electrically connected to the first contact plug. A portion of the support film is removed. A remaining portion of the support film mechanically supports the first electrode. The second insulating film is removed by a wet etching to expose an outside surface of the first electrode while the barrier film prevents the first insulating film from being etched. At least one of the barrier film and the support film is formed by using high density plasma chemical vapor deposition.

### BACKGROUND OF THE INVENTION

1. Field of the Invention

The present invention relates to a method of manufacturing a semiconductor device including a MOS transistor and a capacitor electrically connected to the MOS transistor through a contact plug, the MOS transistor being used as a DRAM (Dynamic Random Access Memory) memory cell.

Priority is claimed on Japanese Patent Application No. 2009-110882, filed Apr. 30, 2009, the content of which is incorporated herein by reference.

2. Description of the Related Art

Recently, the area of a memory cell including DRAM elements has been decreasing with further miniaturization of semiconductor devices. For a capacitor included in a memory cell to have sufficient capacitance, a lower electrode of the capacitor generally has a cylindrical or pillar shape. A sidewall of the lower electrode is used as a capacitor to increase the surface area of the capacitor.

With a decrease in area of a memory cell, the area of a base of the lower electrode is also decreased. For this reason, the lower electrode is likely to collapse in a process of exposing the sidewall of the lower electrode, thereby causing a short-circuit between the collapsed lower electrode and an adjacent lower electrode.

To prevent the lower electrode from collapsing, Japanese Patent Laid-Open Publication Nos. 2003-297952 and 2003-142605 disclose a technique of forming a supporter between lower electrodes to mechanically support the lower electrodes.

To expose the sidewall of the lower electrode, an inter-layer insulating film is removed by wet etching with a solution mainly containing hydrofluoric acid (HF). In this case, it is necessary to selectively remove an inter-layer insulating film, such as a silicon oxide (SiO₂) film, without damaging an insulating support film that forms the supporter.

For this reason, a silicon nitride (Si₃N₄) film having a chemical resistance to hydrofluoric acid is used as the insulating support film. To prevent the hydrofluoric acid from penetrating elements, such as a MOS transistor, and thereby damaging the elements, a silicon nitride film is also used as an inter-layer insulating film for preventing the penetration of a solution.

Generally, a silicon nitride film having a chemical resistance to hydrofluoric acid is formed by LP-CVD (Low Pressure Chemical Vapor Deposition). According to the LP-CVD method, a material gas is deposited using chemical reaction. Therefore, it is necessary to keep a semiconductor substrate at a film forming temperature in the range of 650° C. to 800° C.

For further miniaturization of semiconductor devices, it has been recently required to reduce a thermal budget for a MOS transistor or the like as much as possible. In other words, a reduction in the thermal budget after a MOS transistor is formed enables prevention of short channel effects or the like, and thereby enables formation of high-performance semiconductor devices.

For this reason, if capacitor elements are formed after a MOS transistor is formed, it has been necessary to reduce the thermal budget while keeping the temperature for forming the insulating support film, such as a silicon nitride film, at 650° C. or less.

Parallel plate PE-CVD (Plasma Enhanced Chemical Vapor Deposition) is known as a method of depositing a silicon nitride film at a low temperature. However, the silicon nitride film formed by the parallel plate PE-CVD contains many hydrogen atoms included in a material gas. Therefore, only a film having a low resistance to hydrofluoric acid can be formed. Therefore, the silicon nitride film formed by the parallel plate PE-CVD cannot be used as the insulating support film or the inter-layer insulating film for preventing the penetration of a solution.

Alternatively, a silicon nitride film can be deposited by ALD (Atomic Layer Deposition) at a temperature of approximately 550° C. The silicon nitride film formed by ALD has a greater resistance to hydrofluoric acid than that of the silicon nitride film formed by the parallel plate PE-CVD, but still does not have enough resistance to be used as the insulating support film or the inter-layer insulating film for preventing the penetration of a solution. Further, the ALD method cannot achieve a reduction in a film forming temperature.

In consideration of the above situations, there has been demand for a method of forming an insulating support film for supporting capacitor electrodes, an inter-layer insulating film for preventing the penetration of a solution, or the like by depositing a silicon nitride film having sufficient chemical resistance to hydrofluoric acid at a temperature of 650° C. or less.

### SUMMARY

In one embodiment, a method of manufacturing a semiconductor device may include, but is not limited to the following processes. A first contact plug is formed in a first insulating film. A barrier film is formed on the first insulating film. A second insulating film is formed on the barrier film. A support film is formed on the second insulating film. A first electrode is formed so as to penetrate the support film and the second insulating film. The first electrode is electrically connected to the first contact plug. A portion of the support film is removed. A remaining portion of the support film mechanically supports the first electrode. The second insulating film is removed by a wet etching to expose an outside surface of the first electrode while the barrier film prevents the first insulating film from being etched. At least one of the barrier film and the support film is formed by using high density plasma chemical vapor deposition.

In another embodiment, a method of manufacturing a semiconductor device may include, but is not limited to the following processes. A contact plug is formed in a first insulating film. A barrier film is formed on the first insulating film by using high density plasma chemical vapor deposition. The barrier film comprises silicon nitride. A second insulating film is formed on the barrier film. A part of the second insulating film is removed to form an electrode electrically connected to the contact plug. The second insulating film is removed by a wet etching to expose an outside surface of the electrode while the barrier film prevents the first insulating film from being etched.

In still another embodiment, a method of manufacturing a semiconductor device may include, but is not limited to the following processes. A contact plug is formed in a first insulating film. A second insulating film is formed on the first insulating film. A support film is formed on the second insulating film by using high density plasma chemical vapor deposition. The support film comprises silicon nitride. An electrode is formed so as to penetrate the support film and the second insulating film. The electrode is electrically connected to the contact plug. A portion of the support film is removed. A remaining portion of the support film mechanically supports the electrode. The second insulating film is removed by a wet etching to expose an outside surface of the electrode.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a plane view illustrating a part of a semiconductor device according to a first embodiment of the present invention;

FIG. 2 is a cross-sectional view taken along a line A-A′ shown in FIG. 1;

FIGS. 3 to 11 are cross-sectional views indicative of a process flow illustrating a method of manufacturing the semiconductor device according to the first embodiment;

FIG. 12 is a plane view illustrating positions of capacitor elements included in the semiconductor device according to the first embodiment;

FIG. 13 is a cross-sectional view schematically illustrating an HDP-CVD apparatus used for manufacturing the semiconductor device according to the first embodiment;

FIG. 14 is a cross-sectional view illustrating a semiconductor device according to a third embodiment of the present invention; and

FIG. 15 is a cross-sectional view illustrating a semiconductor device according to a fourth embodiment of the present invention.

### DETAILED DESCRIPTION OF THE PREFERRED EMBODIMENTS

The present invention will now be described herein with reference to illustrative embodiments. The accompanying drawings explain a semiconductor device and a method of manufacturing the semiconductor device in the embodiments. The size, the thickness, and the like of each illustrated portion might be different from those of each portion of an actual semiconductor device.

Those skilled in the art will recognize that many alternative embodiments can be accomplished using the teachings of the present invention and that the present invention is not limited to the embodiments illustrated herein for explanatory purposes.

### First Embodiment

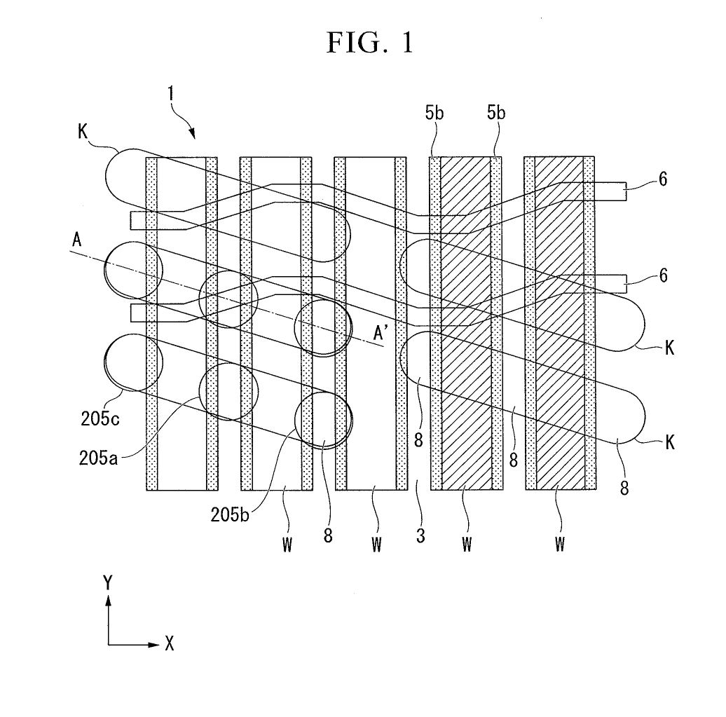

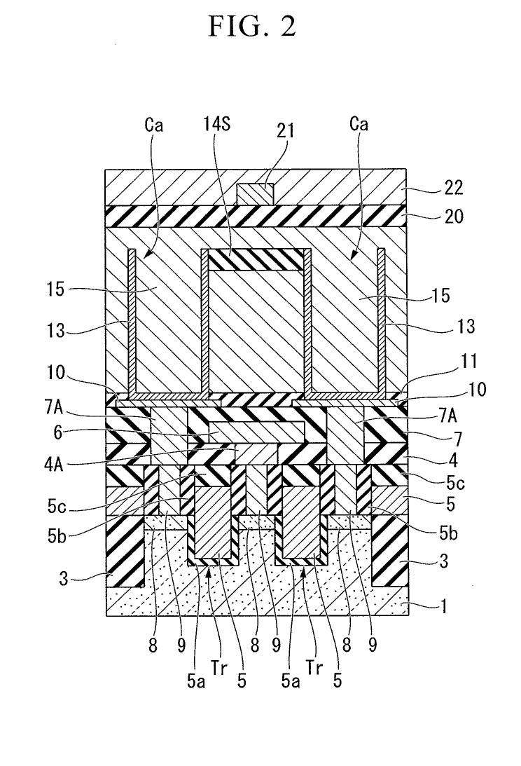

FIG. 1 is a plane view illustrating a part of a semiconductor device according to a first embodiment of the present invention. FIG. 2 is a cross-sectional view taken along a line A-A′ shown in FIG. 1. The right side of FIG. 1 transparently illustrates active regions K and bit wirings 6 over a cross section cutting gate electrodes 5 and sidewalls 5b which form word wirings W as explained later.

As shown in FIG. 1, multiple strip active regions K are aligned at a predetermined interval. The strip active regions K extend toward lower right, thus form the layout of 6F² memory cells.

Impurity diffusion layers 8 are formed in the center region and both side regions of each active region K. The impurity diffusion layers 8 function as S/D (source-and/or-drain) regions of a MOS transistor. Substrate contact portions 205a, 205b, and 205c are formed immediately above the respective S/D regions (impurity diffusion layers) 8. The shape and alignment direction of the active regions K are not limited to those shown in FIG. 1.

Curved bit wirings 6 are aligned at a predetermined interval and extend in the horizontal (X) direction. Straight word wirings W are aligned at a predetermined interval and extend in the vertical (Y) direction. A gate electrode 5 shown in FIG. 5 is formed in a region where the word wiring W crosses the active region K in plane view.

The first embodiment explains a case where a MOS transistor Tr includes a trench gate electrode. Alternatively, a planar MOS transistor or a MOS transistor having a channel region on a side surface of a trench formed in a semiconductor substrate may be used.

As shown in FIG. 2, a memory cell schematically includes a MOS transistor Tr and a capacitor element Ca electrically connected to the MOS transistor Tr through a substrate contact plug 9 and a capacitor contact plug 7A. A semiconductor substrate 1 is made of silicon (Si) containing a p-type impurity at a predetermined concentration. An element isolation region 3 is formed in the semiconductor substrate 1. The element isolation region 3 is formed by embedding an insulating film, such as a silicon oxide film (SiO₂), into a surface of the semiconductor substrate 1 using an STI (Shallow Trench Isolation) method. The element isolation region 3 defines the active regions K.

The first embodiment explains a case where the present invention is applied to a cell structure where a memory cell storing 2 bit of data is disposed in one active region K.

The impurity diffusion layers 8, which will be S/D regions, are separately formed in the semiconductor substrate 1 in the active region K.

The trench gate electrode 5 is formed between each of the impurity diffusion layers 8. The gate electrode 5 is a multi-layered film including a poly-crystalline silicon film and a metal film. The gate electrode 5 upwardly protrudes from the semiconductor substrate 1. The poly-crystalline silicon film can be formed by implanting an impurity, such as phosphorus, at the time of forming the film by CVD.

Alternatively, a poly-crystalline silicon film free of impurities is formed first. Then, in a later process, an n-type or p-type impurity may be ion-implanted into the poly-crystalline silicon film free of impurities. A high melting point metal, such as tungsten (W), tungsten nitride (WN), or tungsten silicide (WSi), may be used as a metal film that forms the gate electrode.

A gate insulating film 5a is formed between the gate electrode 5 and the semiconductor substrate 1. A sidewall 5b, which is an insulating film made of silicon nitride (Si₃N₄) or the like, is formed so as to cover a side surface of the gate electrode 5. Another insulating film made of silicon nitride or the like is formed so as to cover an upper surface of the gate electrode 5.

The impurity diffusion layer 8 is formed by implanting an n-type impurity, such as phosphorus, into the semiconductor substrate 1. The substrate contact plug 9 is formed so as to be in contact with the impurity diffusion layer 8. The substrate contact plugs 9 are disposed at the positions of the substrate contact portions 205c, 205a, and 205b shown in FIG. 1. The substrate contact plug 9 is made of poly-crystalline silicon containing phosphorus. The horizontal width of the substrate contact plug 9 is defined by the sidewall 5b, and thus has a self-alignment structure.

A first lower inter-layer insulating film 4 is formed so as to cover the insulating film 5c and the substrate contact plug 9. A bit-line contact plug 4A is formed so as to penetrate the first lower inter-layer insulating film 4. The bit-line contact plug 4A is disposed at the position of the substrate contact portion 205a. The bit-line contact plug 4A is electrically connected to the substrate contact plug 9.

The bit-line contact plug 4A is formed by depositing tungsten (W) or the like over a barrier film (TiN/Ti) including a titanium (Ti) film and a titanium nitride (TiN) film. A bit wiring 6 is formed so as to connect to the bit-line contact plug 4A. The bit wiring 6 includes a multi-layered film including a tungsten nitride (WN) film and a tungsten (W) film.

A second lower inter-layer insulating film 7 is formed so as to cover the bit wiring 6. A capacitor contact plug 7A is formed so as to penetrate the first and second lower inter-layer insulating films 4 and 7 and to connect to the substrate contact plug 9. The capacitor contact plugs 7A are disposed at the positions of the substrate contact portions 205b and 205c shown in FIG. 1.

A capacitor contact pad 10 is formed over the second lower inter-layer insulating film 7 so as to electrically connect to the capacitor contact plug 7A. The capacitor contact pad 10 includes a multi-layered film including a tungsten nitride (WN) film and a tungsten (W) film.

A first inter-layer insulating film 11 is formed so as to cover the capacitor contact pad 10. The first inter-layer insulating film 11 prevents hydrofluoric acid, which is used for wet etching, from penetrating the MOS transistor at the time of wet etching. A capacitor element Ca is formed so as to penetrate the first inter-layer insulating film 11 and to connect to the capacitor contact pad 10.

The capacitor element Ca includes lower and upper electrodes 13 and 15, and a capacitor insulating film (not shown) between the lower and upper electrodes 13 and 15. The lower electrode 13 is electrically connected to the capacitor contact pad 10.

In this embodiment, the lower electrode has a cylindrical shape, and the capacitor element Ca is formed as a crown type.

A supporter 14S, which is made of an insulating support film 14, connects the adjacent lower electrodes 13, thereby preventing the lower electrodes 13 from collapsing during the manufacturing processes.

In a peripheral circuit region other than the memory cell region, the capacitor element Ca for storing data is not formed, and a second inter-layer insulating film (not shown) made of silicon oxide or the like is formed over the first inter-layer insulating film 11.

In the memory cell region, a third inter-layer insulating film 20, a wiring layer 21 made of aluminum (Al), copper (Cu), or the like, and a protection film 22 are formed over the capacitor element Ca.

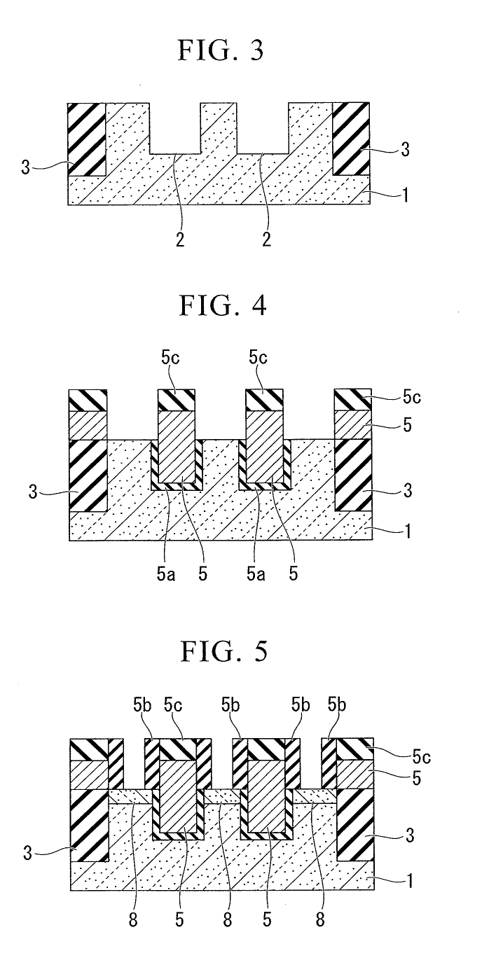

Hereinafter, a method of manufacturing the semiconductor device according to the first embodiment is explained with reference to FIGS. 3 to 11. FIGS. 3 to 11 are cross-sectional views taken along a line A-A′ shown in FIG. 1.

As shown in FIG. 3, the element isolation region 3 is formed to define active regions K on a main surface of the semiconductor substrate 1 made of p-type silicon. The element isolation region 3 is formed by embedding an insulating film, such as a silicon oxide film, into the semiconductor substrate 1 using the STI method.

Then, a trench pattern 2, which is a basis for forming a gate electrode of the MOS transistor, is formed. The trench pattern 2 is formed by anisotropically etching the semiconductor substrate 1 using a photoresist pattern (not shown) as a mask.

Then, a silicon surface of the semiconductor substrate 1 is thermally oxidized to form a silicon oxide film having a thickness of approximately 4 nm, as shown in FIG. 4.

The silicon oxide film forms the gate insulating film 5a in the transistor formation region. A multi-layered film including a silicon oxide film and a silicon nitride film, a High-k film (high dielectric film), or the like may be used as the gate insulating film 5a.

Then, a poly-crystalline silicon film containing an n-type impurity is formed over the gate insulating film 5a by CVD with a material gas containing monosilane (SiH₄) and phosphine (PH₃). In this case, the thickness of the poly-crystalline silicon film is determined such that the poly-crystalline silicon film fully fills the trench pattern 2.

Alternatively, after a poly-crystalline silicon film free of impurities, such as phosphorus, is formed, a desired impurity may be ion implanted into the poly-crystalline silicon film in the following process.

Then, a metal film is deposited by sputtering at a thickness of approximately 50 nm over the poly-crystalline silicon film. The metal film is a high melting point metal, such as tungsten, tungsten nitride, and tungsten silicide. The multi-layered film including the poly-crystalline film and the metal film will become the gate electrode 5 through the following processes.

Then, the insulating film 5c made of silicon nitride is deposited at a thickness of approximately 70 nm over the metal film forming the gate electrode 5. The insulating film 5c is deposited by parallel plate PE-CVD with a material gas containing monosilane and ammonia (NH₃).

Then, a photoresist (not shown) is applied over the insulating film 5c. Then, a photoresist pattern for forming the gate electrode 5 is formed by lithography using a predetermined mask. Then, the insulating film Sc is anisotropically etched using the photoresist pattern as a mask.

After the photoresist pattern is removed, the metal film and the poly-crystalline film are etched using the insulating film 5c as a hard mask to form the gate electrode 5. The gate electrode 5 functions as the word line W shown in FIG. 1.

Then, an n-type impurity, such as phosphorus, is ion-implanted into the semiconductor substrate 1 in the active region, which is not covered by the gate electrode 5. Thus, the impurity diffusion layer 8 is formed as shown in FIG. 5.

Then, a silicon nitride film is deposited by LP-CVD at the thickness of approximately 20 to 50 nm over the entire surface, and then is etched back. Thus, the sidewall 5b covering the side surface of the gate electrode 5 is formed. At this time, a MOS transistor Tr is not complete, and therefore the effect of thermal treatment is small. For this reason, LP-CVD at a high temperature may be used.

Then, an inter-layer insulating film (not shown), such as a silicon oxide film, is formed by CVD so as to cover the insulating film 5c and the sidewall 5b. Then, a surface of the inter-layer insulating film (not shown) is polished by CMP (Chemical Mechanical Polishing) to be planarized until an upper surface of the insulating film 5c is exposed.

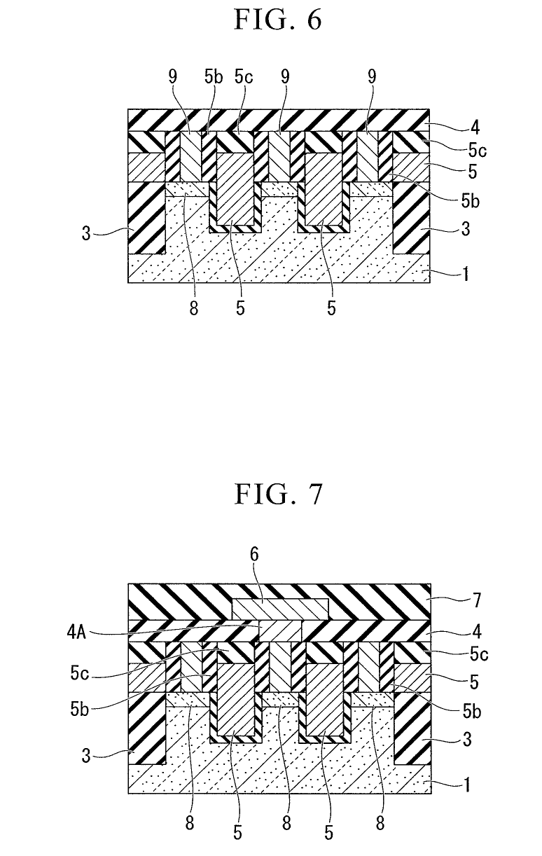

Then, the substrate contact plug 9 is formed as shown in FIG. 6. Specifically, the inter-layer insulating film (not shown) is removed by etching using a photoresist pattern as a mask to form holes at the positions of the substrate contact portions 205a, 205b, and 205c.

Then, holes are formed between each of the gate electrodes 5 by self-alignment using the insulating film 5c and the sidewall 5b. Then, a poly-crystalline silicon film containing phosphorus is deposited by CVD. The poly-crystalline silicon film filling the holes becomes the substrate contact plug 9.

Then, the poly-crystalline silicon film over the insulating film 5c is removed by CMP so as to expose an upper surface of the substrate contact plug 9 filling the holes.

Then, the first lower inter-layer insulating film 4 made of silicon oxide is formed by CVD at the thickness of approximately 600 nm over the insulating film 5c and the substrate contact plug 9.

Then, an upper surface of the first lower inter-layer insulating film 4 is planarized by CMP until the first lower inter-layer insulating film 4 has a thickness of approximately 300 nm.

Then, a contact hole is formed in the first lower inter-layer insulating film 4 at the position of the substrate contact portion 205a shown in FIG. 1, as shown in FIG. 7. Then, a multi-layered film including a barrier film such as a TiN/Ti film, and a tungsten (W) film over the barrier film is deposited so as to fill the contact hole.

Then, an upper surface of the multi-layered film is polished by CMP to form the bit-line contact plug 4A. Then, the bit wiring 6 is formed so as to connect to the bit-line contact plug 4A. Then, the second lower inter-layer insulating film 7 made of silicon oxide or the like is formed so as to cover the bit wiring 6.

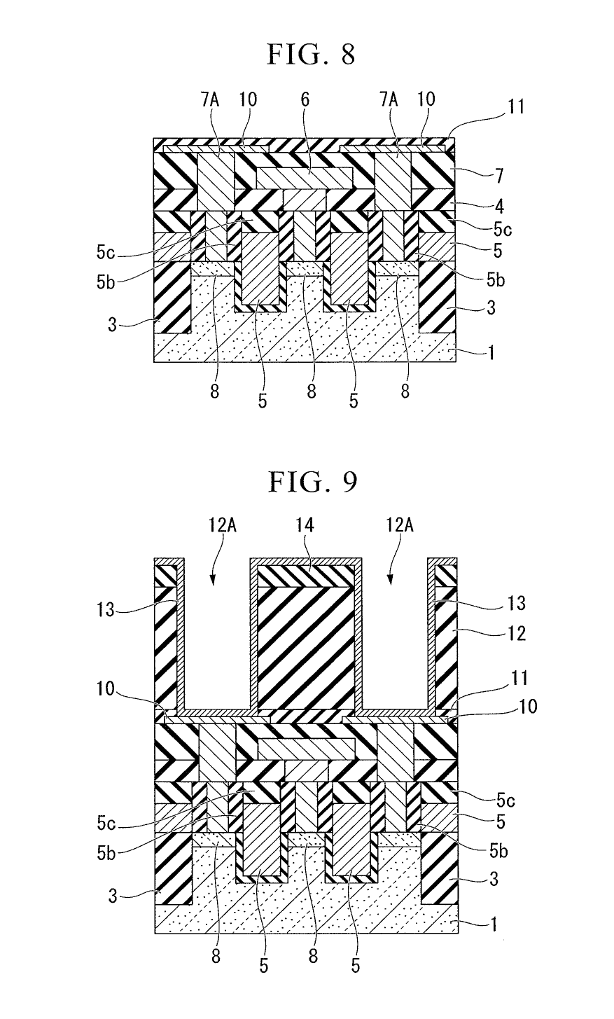

Then, contact holes are formed at the positions of the substrate contact portions 205b and 205c shown in FIG. 1 so as to penetrate the first and second lower inter-layer insulating films 4 and 7 and to expose the upper surface of the substrate contact plug 9, as shown in FIG. 8.

Then, a multi-layered film including a barrier film such as a TiN/Ti film, and a tungsten (W) film over the barrier film is deposited so as to fill the contact holes. Then, an upper surface of the multi-layered film is polished by CMP to form the capacitor contact plug 7A.

Then, the capacitor contact pad 10 is formed over the second lower inter-layer insulating film 7 using a multi-layered film containing tungsten. The capacitor contact pad 10 is electrically connected to the capacitor contact plug 7A. The main surface of the capacitor contact pad 10 is larger in size than a lower surface of the lower electrode of the capacitor element Ca that is explained later.

Then, a silicon nitride film is formed by LP-CVD so as to cover the capacitor contact pad 10. Thus, the first inter-layer insulating film 11 having a thickness of, for example, 60 nm is formed. The silicon nitride film that forms the first inter-layer insulating film 11 may be formed by HDP-CVD (High Density Plasma Chemical Vapor Deposition) to reduce the film forming temperature, as will be explained later.

Then, a second inter-layer insulating film 12 made of silicon oxide or the like is deposited at a thickness of, for example, 2 μm over the first inter-layer insulating film 11, as shown in FIG. 9. Then, the insulating support film 14 made of silicon nitride is formed at a thickness of approximately 50 nm by HDP-CVD. The insulating support film 14 forms a supporter 14S.

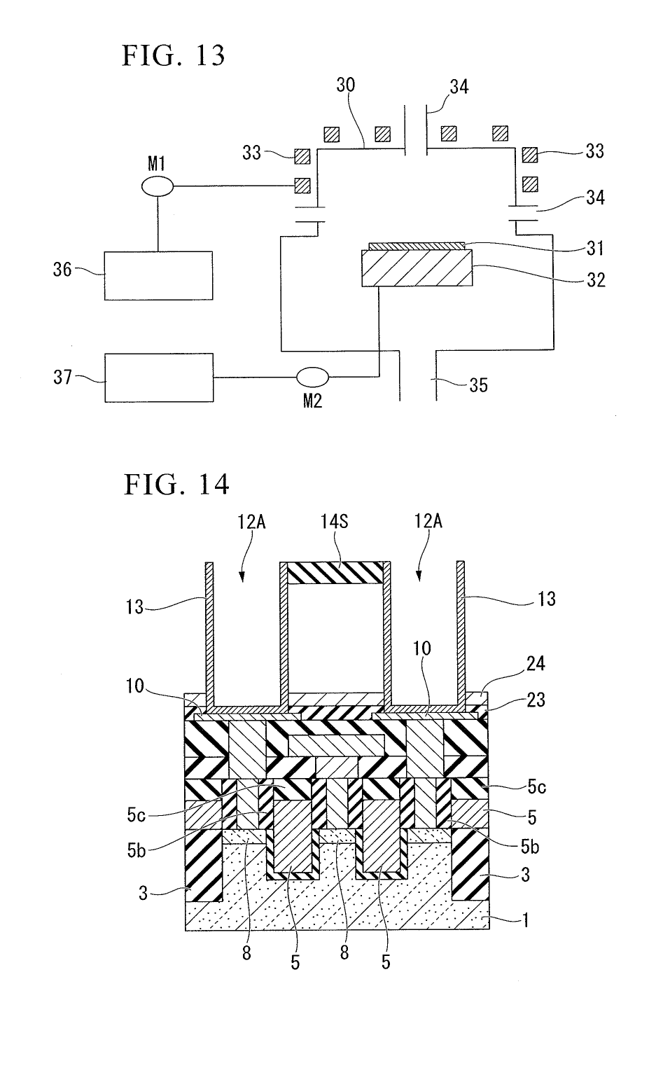

Hereinafter, a method of forming a silicon nitride film by HDP-CVD is explained. FIG. 13 is a cross-sectional view illustrating a configuration of an HDP-CVD apparatus.

A semiconductor substrate 31 is placed on a stage 32 in a chamber 30. The chamber 30 includes a supply pipe 34 for supplying a material gas into the chamber 30. The material gas after reaction is released from the chamber 30 through a release pipe 35.

The pressure in the chamber 30 is maintained at a predetermined value using a turbo-molecular pump (not shown). Coils 33 are placed along the chamber 30. An RF generator 36 supplies high-frequency power (source power) to the coils 33 through a matching unit Ml, and thereby generates inductively-coupled plasma in the chamber 30.

Another RF generator 37 supplies high-frequency power (bias power) to the stage 32 through a matching unit M2. The HDP-CVD apparatus independently controls the source power and the bias power to control movement of ions for forming a film and to adjust a state of a film to be deposited.

When a silicon nitride film is deposited using the HDP-CVD apparatus, a silane (SiH₄) gas and a nitrogen (N₂) gas are used as a material gas. Further, an inactive gas, such as an argon (Ar) gas, is used as a carrier gas.

A temperature of the semiconductor substrate 31 on the stage 32 is set to be in the range of 400° C. to 500° C. The flow amounts of the SiH₄ gas, the N₂ gas, and the Ar gas are set to, for example, 50 sccm, 1200 sccm, and 200 sccm, respectively. Then, the source power of 8000 W is applied without the bias power to generate plasma in the chamber 30. Thus, a silicon nitride film can be deposited over the semiconductor substrate 31.

The refractive index of the silicon nitride film formed under the above conditions was in the range of 1.99 to 2.01. The refractive index reflects a composition of the deposited film. If the refractive index is approximately 2.0, it can be determined that the silicon nitride film has a chemical resistance to hydrofluoric acid.

The etching rate of the silicon nitride film formed by HDP-CVD to hydrofluoric acid and the etching rate of the silicon nitride film formed by the conventional LP-CVD (at two film forming temperatures) were measured. Table 1 illustrates the etching rate of each film compared to the etching rate of the silicon nitride film formed by HDP-CVD.

TABLE 1

| TYPE OF FILM | ETCHING RATE |
|---|---|
| HDP-CVD | 1 |
| LP-CVD (680° C.) | 1.9 |
| LP-CVD (630° C.) | 5.5 |

When the silicon nitride film is formed by LP-CVD, the chemical resistance to hydrofluoric acid can be increased by increasing the film forming temperature, as shown in Table 1. Even when the silicon nitride film is formed by LP-CVD at 680° C., the silicon nitride film formed by HDP-CVD has a greater resistance than the silicon nitride film formed by LP-CVD. Consequently, a support film having a better resistance to hydrofluoric acid can be formed by HDP-CVD at a temperature lower than that of the conventional case.

After the insulating support film 14 is formed as shown in FIG. 9, holes 12A are formed by anisotropic dry etching at positions where capacitor elements are to be formed so as to expose an upper surface of the capacitor contact pad 10.

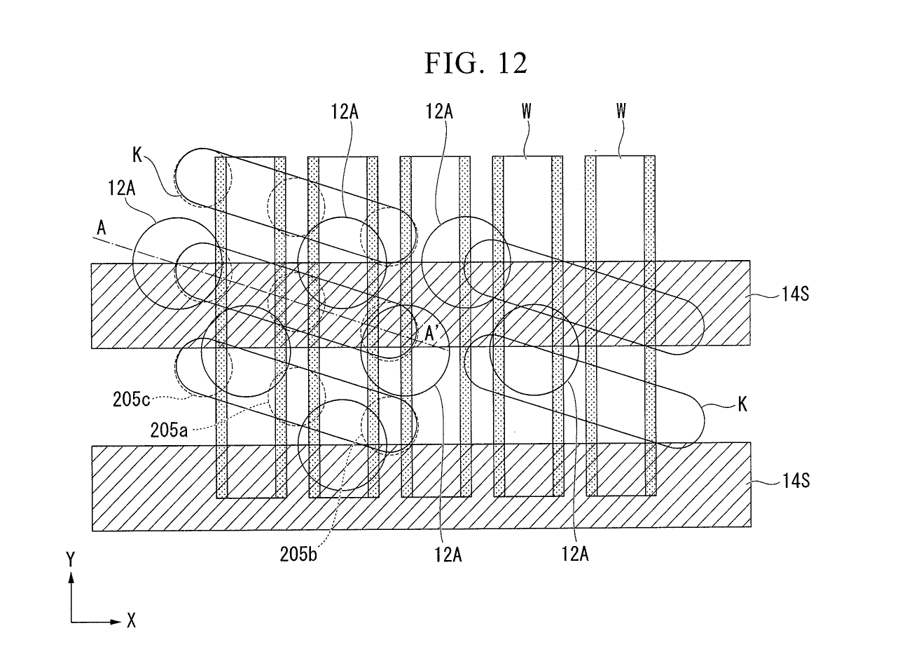

FIG. 12 is a plane view illustrating the positions where capacitor elements are to be formed. As shown in FIG. 12, lower electrodes of capacitor elements are formed at the positions of the holes 12A. The capacitor contact pad and the bit wiring are omitted in FIG. 12.

After the holes 12A are formed, the lower electrodes 13 of the capacitor element Ca is formed. Specifically, a titanium nitride film is deposited so as not to fully fill the hole 12A, as shown in FIG. 9. A metal film other than the titanium nitride film may be used as the lower electrode 13.

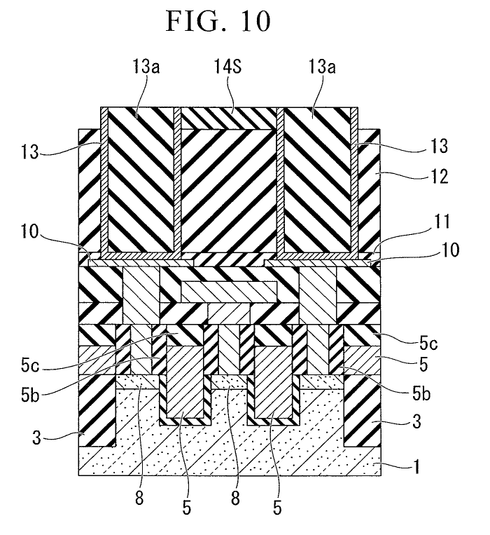

Then, a silicon oxide film 13a or the like fills the holes 12A so as to protect the lower electrodes 13 in the holes 12A, as shown in FIG. 10. Then, the main surface of the silicon oxide film 13a is polished by CMP until an upper surface of the lower electrode 13 is exposed.

Then, the insulating support film 14 is patterned using a photoresist pattern as a mask so as to form the supporter 14S. The supporter 14S prevents the lower electrodes 13 from collapsing.

FIG. 12 illustrates an arrangement example of the supporter 14S. The pattern of the insulating support films 14 is a strap-shaped pattern extending in the X direction over the photo mask. After the insulating support film 14 is formed, the holes 12A are formed. For this reason, the supporter 14S remains only outside the holes 12A after a transcription using the photo mask.

The supporter 14S connects the adjacent lower electrodes 13 in the extending direction and extends to the end of the memory cell region, and thereby stably mechanically supports the lower electrodes 13.

Further, the supporter 14S extends over the peripheral circuit region other than the memory cell region, and thereby prevents an etching solution (hydrofluoric acid) from penetrating the peripheral circuit region at the time of wet etching.

The shape and the extending direction of the supporter 14S are not limited to those shown in FIG. 12. It is enough for the supporter 14S to partially overlap each hole 12A in plane view.

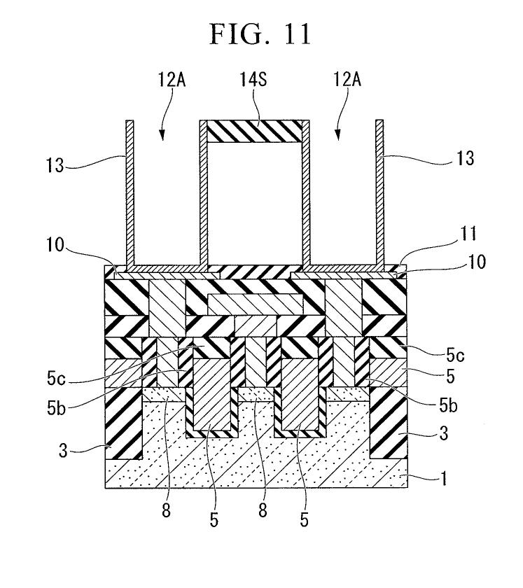

Then, the second inter-layer insulating film 12 in the memory cell region is removed by wet etching with hydrofluoric acid (HF) so as to expose outer surfaces of the lower electrodes 13, as shown in FIG. 11. The first inter-layer insulating film 11 made of silicon nitride prevents the etching solution from penetrating the MOS transistor in the lower layer. Thus, the MOS transistor is prevented from being etched.

The insulating support film 14 remains over the first inter-layer insulating film 11 in the peripheral circuit region, and thereby prevents the penetration of the etching solution. The lower electrodes 13 are mechanically supported by the supporter 14S, and thereby are prevented from collapsing at the time of wet etching.

Then, a capacitor insulating film (not shown) is formed so as to cover the side surfaces of the lower electrodes 13. A high dielectric film, such as a hafnium oxide (HfO₂) film, a zirconium oxide (ZrO₂) film, an aluminum oxide (Al₂O₃) film, or a multi-layered film including those films, may be used as the capacitor insulating film.

Then, the upper electrode 15 of the capacitor element Ca, which is made of titanium nitride, is formed. The lower and upper electrodes 13 and 15, and the capacitor insulating film between the lower and upper electrodes 13 and 15 form the capacitor element.

Then, the third inter-layer insulating film 20 made of silicon oxide is formed. A contact plug (not shown) for applying a voltage to the upper electrode 15 is formed in the memory cell region. Then, the wiring layer 21 made of aluminum (Al) and copper (Cu) is formed. Then, the protection film 22 made of silicon oxynitride (SiON) or the like is formed. Thus, the memory cell of a DRAM element is complete.

### Second Embodiment

Whether or not the silicon nitride film, which forms the first inter-layer insulating film 11, prevents the penetration of an etching solution at the time of wet etching was examined. As a result, the following problems arose when the silicon nitride film was formed by HDP-CVD.

According to the memory cell structure shown in FIG. 2, the capacitor element Ca electrically connects to the capacitor contact plug 7A through the capacitor contact pad 10. For this reason, when the silicon nitride film is formed by HDP-CVD, the silicon nitride film is likely to be thinner at the edge portion of the capacitor contact pad 10, thereby causing generation of pinholes. Consequently, the function of the silicon nitride film preventing the penetration of the etching solution degrades.

After consideration of the deposition condition for the silicon nitride film, the present inventor found that the above problem can be solved by applying bias power when the silicon nitride film is formed by HDP-CVD.

Specifically, a silicon nitride film was deposited by HDP-CVD under the conditions that the flow amounts of an SiH₄ gas, an N₂ gas, and an Ar gas were 200 sccm, 400 sccm, and 200 sccm, respectively, the source power was 8000 W, and the bias power was 1000 W. The film forming temperature may be set to be in the range of 400° C. to 500° C. as explained above.

The thickness of the silicon nitride film formed in this manner was not reduced in thickness at step portions of the underlying pattern, thereby preventing generation of pinholes. Additionally, the etching rate of the silicon nitride film to hydrofluoric acid was measured. As a result, the etching rate of the silicon nitride film formed with the bias power was two times greater than that of the silicon nitride film formed without the bias power. The etching rate of the silicon nitride film formed with the bias power was much smaller than the etching rate (5.5) of the silicon nitride film formed by LP-CVD (at 630° C.) shown in Table 1.

Further, the etching rate of the silicon nitride film, which is deposited by ALD (Atomic Layer Deposition) at a lower temperature than that in the case of LP-CVD, was measured. As a result, the obtained etching rate was approximately 2.9 times greater than the etching rate of the silicon nitride film formed by HDP-CVD without the bias power.

Thus, the etching resistance to hydrofluoric acid slightly degrades when the silicon nitride film is deposited with the bias power compared to when the silicon nitride film is deposited without the bias power. However, the silicon nitride film that prevents generation of pinholes could be formed at a temperature of 500° C. or less.

The thickness of the silicon nitride film to be deposited may be adjusted according to the time for the silicon nitride film to be subjected to hydrofluoric acid at the time of wet etching. The insulating support film 14 of the capacitor element Ca and the second inter-layer insulating film 11 for preventing the penetration of the etching solution are formed by HDP-CVD, thereby further reducing the thermal budget for the semiconductor device compared to the conventional case.

### Third Embodiment

As explained above, the chemical resistance to hydrofluoric acid slightly degrades when the silicon nitride film is formed by HDP-CVD with the bias power than when the silicon nitride film is formed without the bias power. Therefore, a multi-layered film including a silicon nitride film formed by HDP-CVD without the bias power and a silicon nitride film formed by HDP-CVD with the bias power may be formed as the first inter-layer insulating film 11.

FIG. 14 illustrates a multi-layered structure of the film for preventing the penetration of an etching solution, which is under the capacitor element. A reference numeral 23 denotes a silicon nitride film (having a thickness of approximately 40 nm) formed by HDP-CVD with the bias power. The reference numeral 24 denotes a silicon nitride film (having a thickness of approximately 30 nm) formed by HDP-CVD without the bias power.

The silicon nitride film 23 is formed first with the bias power. Therefore, a decrease in the thickness of the capacitor contact pad 10 at the edge portion thereof can be reduced. Then, the silicon nitride film 24 is formed without the bias power. As a result, the silicon nitride multi-layered film having a greater chemical resistance can be formed without generating pinholes.

The silicon nitride multi-layered film may include three or more silicon nitride films. Those silicon nitride films may be formed by repeating a set of forming a silicon nitride film with the bias power and forming a silicon nitride film without the bias power.

The silicon nitride film formed with the bias power effectively prevents generation of pinholes not only when an underlying layer has a step portion caused by a pattern, such as a wiring layer or a pad, but also when the underlying layer has a step portion caused by foreign matter being included in the inter-layer insulating film during the manufacturing process.

Therefore, a silicon nitride multi-layered film may be used as the insulating support film 14 for supporting a capacitor element under which the underlying layer has no step portion. In this case, the silicon nitride multi-layered film preferably includes bottom, middle, and top silicon nitride films. The bottom and top silicon nitride films are subjected to hydrofluoric acid for a longer time than the middle silicon nitride film. For this reason, the bottom and top silicon nitride films are preferably formed without the bias power. The middle silicon nitride film is preferably formed with the bias power.

### Fourth Embodiment

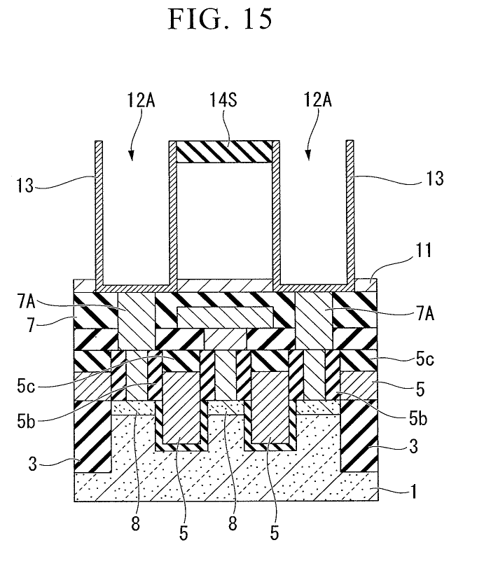

As shown in FIG. 15, the lower electrode 13 of the capacitor element may be directly connected to the capacitor contact plug 7A. In this case, the upper surface of the second lower inter-layer insulating film 7 has already been planarized by CMP. For this reason, a single-layered silicon nitride film 11 is formed by HDP-CVD without the bias power. Thus, the silicon nitride film 11 for preventing the penetration of an etching solution, which has the excellent chemical resistance, can be formed.

A more reduction in the thermal budget can be achieved by forming, by HDP-CVD, both the insulating support film and the film for preventing the penetration of an etching solution. However, only if at least one of the insulating support film and the film for preventing the penetration of an etching solution is formed by HDP-CVD, a greater reduction in the thermal budget than the conventional case can be achieved. The lower electrode may have a pillar shape.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percent of the modified term if this deviation would not negate the meaning of the word it modifies.

It is apparent that the present invention is not limited to the above embodiments, but may be modified and changed without departing from the scope and spirit of the invention.

What is claimed is:

1. A method of manufacturing a semiconductor device, comprising:
forming a first contact plug in a first insulating film;
forming a barrier film on the first insulating film;
forming a second insulating film on the barrier film;
forming a support film on the second insulating film;
forming a first electrode penetrating the support film and the second insulating film, the first electrode being electrically connected to the first contact plug;
removing a portion of the support film, a remaining portion of the support film mechanically supporting the first electrode; and
removing the second insulating film by a wet etching to expose an outside surface of the first electrode while the barrier film prevents the first insulating film from being etched,
wherein at least one of the barrier film and the support film is formed by using high density plasma chemical vapor deposition.

2. The method according to claim 1, further comprising:
before forming the barrier film, forming a contact pad on the first insulating film, the first electrode being electrically connected to the first contact plug through the contact pad.

3. The method according to claim 1, wherein the barrier film is formed by using high density plasma chemical vapor deposition with bias power.

4. The method according to claim 1, wherein forming the barrier film comprising:
forming a first barrier layer on the first insulating film by using high density plasma chemical vapor deposition with bias power; and
forming a second barrier layer on the first barrier layer by using high density plasma chemical vapor deposition without bias power.

5. The method according to claim 4, wherein forming the barrier film further comprises:
forming a third barrier layer on the second barrier layer by using high density plasma chemical vapor deposition.

6. The method according to claim 1, wherein the first electrode is in contact with a top surface of the first contact plug.

7. The method according to claim 1, wherein forming the support film comprises:
forming a first support layer on the second insulating film by using high density plasma chemical vapor deposition without bias power;
forming a second support layer on the first support layer by using high density plasma chemical vapor deposition with bias power; and
forming a third support layer on the second support layer by using high density plasma chemical vapor deposition without bias power.

8. The method according to claim 1, wherein
the barrier film comprises silicon nitride, and
the support film comprises silicon nitride.

9. The method according to claim 1, wherein
a second contact plug is formed in the first insulating film at the same time of forming the first contact plug,
a second electrode penetrating the support film and the second insulating film is formed at the same time of forming the first electrode,
the second electrode is electrically connected to the second contact plug,
an outside surface of the second electrode is exposed by the wet etching, and
the remaining portion of the support film connects the first and second electrodes so as to mechanically support the first and second electrodes.

10. The method according to claim 9, wherein the remaining portion of the support film partially connects to outside surfaces of the first and second electrodes.

11. The method according to claim 8, wherein the high density plasma chemical vapor deposition is performed at a temperature in the range of 400° C. to 500° C.

12. The method according to claim 1, wherein the second insulating film comprises silicon oxide, and the wet etching is performed by using hydrofluoric acid.

13. The method according to claim 9, wherein
the semiconductor device has a memory cell region and a peripheral circuit region other than the memory cell region,
the memory cell region comprises the first and second contact plugs and the first and second electrodes,
the remaining portion of the support film extends over the memory cell region and the peripheral circuit region, and
the remaining portion of the support film prevents the second insulating film in the peripheral circuit region from being etched during removing the second insulating film by the wet etching.

14. The method according to claim 1, further comprising:
forming a capacitor insulating film on a surface of the first electrode after removing the second insulating film; and
forming a third electrode on a surface of the capacitor insulating film.

15. The method according to claim 1, wherein the first electrode has a cylindrical shape.

16. A method of manufacturing a semiconductor device, comprising:
forming a contact plug in a first insulating film;
forming a barrier film on the first insulating film by using high density plasma chemical vapor deposition, the barrier film comprising silicon nitride;
forming a second insulating film on the barrier film;
removing a part of the second insulating film to form an electrode electrically connected to the contact plug; and
removing the second insulating film by a wet etching to expose an outside surface of the electrode while the barrier film prevents the first insulating film from being etched.

17. The method according to claim 16, wherein the high density plasma chemical vapor deposition is performed at a temperature in the range of 400° C. to 500° C.

18. The method according to claim 16, wherein forming the barrier film comprising:
forming a first barrier layer on the first insulating film; and
forming a second barrier layer on the first barrier layer,
wherein one of the first and second barrier layers is formed by using high density plasma chemical vapor deposition with bias power, and the other of the first and second barrier layers is formed by using high density plasma chemical vapor deposition without bias power.

19. A method of manufacturing a semiconductor device, comprising:
forming a contact plug in a first insulating film;
forming a second insulating film on the first insulating film;
forming a support film on the second insulating film by using high density plasma chemical vapor deposition, the support film comprising silicon nitride;
forming an electrode penetrating the support film and the second insulating film, the electrode being electrically connected to the contact plug;
removing a portion of the support film, a remaining portion of the support film mechanically supporting the electrode; and
removing the second insulating film by a wet etching to expose an outside surface of the electrode.

20. The method according to claim 19, wherein forming the support film comprises:
forming a first support layer on the second insulating film; and
forming a second support layer on the first support layer,
wherein one of the first and second support layers is formed by using high density plasma chemical vapor deposition with bias power, and the other of the first and second support layers is formed by using high density plasma chemical vapor deposition without bias power.
